(19) United States
(12) Patent Application Publication
(10) Pub. No.: US 2015/0235966 A1
(43) Pub. Date: Aug. 20, 2015

(54) WIRING BOARD AND SEMICONDUCTOR DEVICE USING THE SAME

(71) Applicant: KABUSHIKI KAISHA TOSHIBA, Minato-ku (JP)

(72) Inventor: Hajime OHHASHI, Yokohama-shi (JP)

(73) Assignee: KABUSHIKI KAISHA TOSHIBA, Minato-ku (JP)

(21) Appl. No.: 14/315,787

(22) Filed: Jun. 26, 2014

(30) Foreign Application Priority Data
Feb. 19, 2014 (JP) 2014-029283

(51) Int. Cl. H01L 23/552; H01L 23/498; H05K 1/02; H01L 23/31

(52) U.S. Cl. CPC H01L 23/552; H01L 23/3107; H01L 23/49838; H05K 1/0298; H05K 1/0216

(57) ABSTRACT

A wiring board of an embodiment includes an insulating substrate and a wiring layer provided on the insulating substrate. The wiring layer has external connection terminals including a ground terminal. The wiring layer is covered by an insulating layer having holes for exposing the external connection terminals. The insulating layer has an opening for exposing the ground terminal toward a side surface of the wiring board. The opening is provided continuously from at least one of the holes. A semiconductor chip mounted on the wiring board is sealed by a sealing resin layer. An upper surface and side surfaces of the sealing resin layer and the side surfaces of the wiring board are covered by a conductive shield layer. The conductive shield layer is electrically connected to the ground terminal via a connection formed in the opening.

### CROSS REFERENCE TO RELATED APPLICATION

This application is based upon and claims the benefit of priority from Japanese Patent Application No. 2014-029283, filed on Feb. 19, 2014; the entire contents of which are incorporated herein by reference.

### FIELD

Embodiments described herein relate generally to a wiring board and a semiconductor device using the same.

### BACKGROUND

In semiconductor devices used in communication equipment and so on, a structure in which a package surface is covered by a shield layer is used in order to suppress electromagnetic troubles such as EMI (Electro Magnetic Interference). As a semiconductor device having a shielding function, there has been known a structure having a shield layer provided along an upper surface and side surfaces of a sealing resin layer which seals a semiconductor chip mounted on a wiring board. As the shield layer, a metal layer having conductivity is used, for instance. The conductive metal layer functions as the shield layer by being electrically connected to ground wiring lines and ground terminals of the wiring board. The conductive metal layer as the shield layer is electrically connected to the ground wiring lines led out to the side surfaces of the wiring board, for instance.

In order to electrically connect the shield layer made of the conductive metal layer and the ground wiring lines of the wiring board, the wiring board used in the semiconductor device with the shielding function has wiring lines for leading out the ground wiring lines to the side surfaces of the wiring board, in addition to ordinary wiring lines necessary for the function as the semiconductor device. Therefore, the wiring board used in the semiconductor device with the shielding function needs to be designed separately from a wiring board used in an ordinary semiconductor device, which is a cause of increasing manufacturing cost of the wiring board. In a wiring board used in a small semiconductor device, space where to provide the lead-out wiring lines of the ground wiring lines is narrow, which is liable to make the routing itself of the wiring lines difficult. This has given rise to a demand for an art to electrically connect the conductive shield layer and the ground wiring lines without employing specialized lead-out wiring lines.

### BRIEF DESCRIPTION OF THE DRAWINGS

FIG. 1A and FIG. 1B are views illustrating a semiconductor device of an embodiment.

FIG. 2A and FIG. 2B are enlarged views of part of a wiring board used in the semiconductor device of the embodiment.

FIG. 3A and FIG. 3B are enlarged views of part of the semiconductor device of the embodiment.

FIG. 4 is an enlarged view of part of a modification example of the wiring board of the embodiment.

FIG. 5 is an enlarged view of part of a semiconductor device using the wiring board illustrated in FIG. 4.

### DETAILED DESCRIPTION

According to one embodiment, there is provided a wiring board including: an insulating substrate; a first wiring layer provided on a first surface side of the insulating substrate; a second wiring layer provided on a second surface side of the insulating substrate and having external connection terminals including a ground terminal; and an insulating layer formed to cover the second wiring layer. The insulating layer has holes for exposing the external connection terminals respectively, and an opening for exposing the ground terminal out of the external connection terminals toward a side surface of the insulating substrate. The opening is provided continuously from at least one of the holes.

According to another embodiment, there is provided a semiconductor device including: the wiring board of the embodiment; a semiconductor chip mounted on a first surface side of the wiring board and electrically connected to the first wiring layer; a sealing resin layer provided on the first surface side of the wiring board to seal the semiconductor chip; a conductive shield layer provided to cover an upper surface and side surfaces of the sealing resin layer and side surfaces of the wiring board; and a connection provided in the opening to electrically connect the ground terminal and the conductive shield layer.

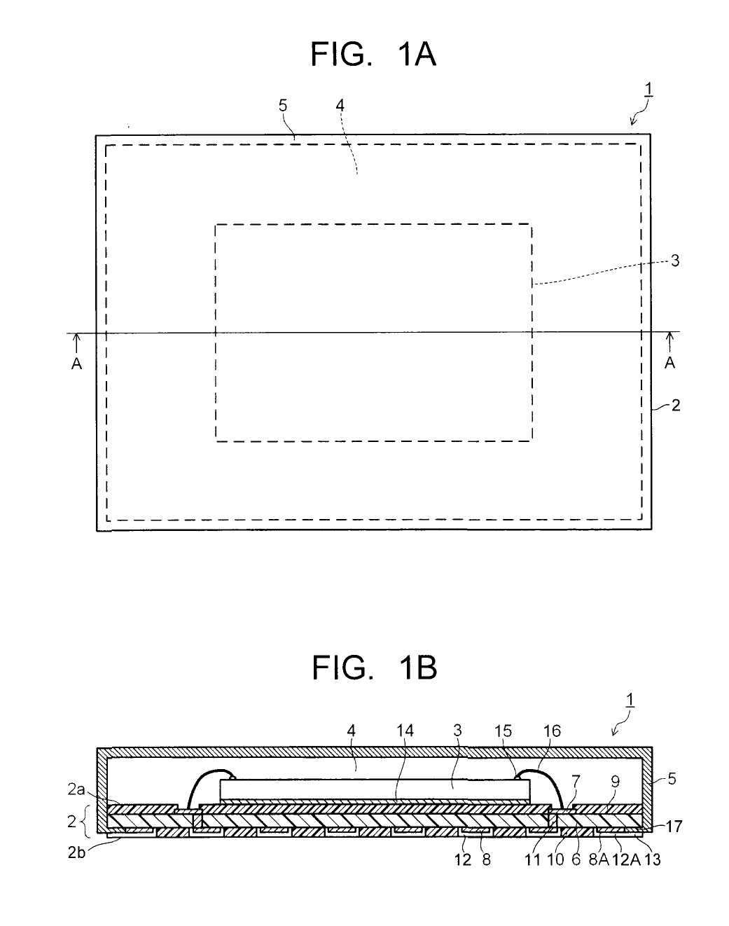

Hereinafter, the wiring board and the semiconductor device of the embodiments will be described with reference to the drawings. FIG. 1A is a top view of the semiconductor device of the embodiment. FIG. 1B is a cross-sectional view taken along A-A line in FIG. 1A. The semiconductor device 1 illustrated in FIG. 1A and FIG. 1B is a shielded semiconductor device (semiconductor package) including: a wiring board 2, a semiconductor chip 3 mounted on a first surface 2a of the wiring board 2, a sealing resin layer 4 sealing the semiconductor chip 3, and a conductive shield layer 5 covering an upper surface and side surfaces of the sealing resin layer 4 and side surfaces of the wiring board 2. Note that, in the description of the embodiments, the upper and lower directions as mentioned in the upper surface of the sealing resin layer 4 and so on are based on the case where the first surface 2a of the wiring board 2 on which the semiconductor chip 3 is mounted is defined as the upper side.

The wiring board 2 has an insulating resin substrate as an insulating substrate 6. On an upper surface (first surface) of the insulating substrate 6, a first wiring layer having internal connection terminals 7 serving as electrical connections with the semiconductor chip 3 is provided. On a lower surface (second surface) of the insulating substrate 6, a second wiring layer having external connection terminals 8 serving as electrical connections with an external device and so on is provided. The external connection terminals 8 include a ground terminal 8A. On the first and second wiring layers, solder resist layers 9, 10 as insulating layers are formed respectively. The first wiring layer and the second wiring layer are electrically connected via vias 11 provided so as to penetrate through the insulating substrate 6.

The solder resist layer 10 provided on a second surface 2b of the wiring board 2 has holes 12 for exposing the external connection terminals 8, respectively. The solder resist layer 10 is provided so as to cover the second surface of the insulating substrate 6 while exposing the external connection terminals 8 toward the lower side of the wiring board 2. The solder resist layer 10 further has an opening 13 for exposing the ground terminal 8A out of the external connection terminals toward the side surface of the wiring board 2. The opening 13 is provided continuously from the hole 12A for exposing the ground terminal 8A toward the lower side of the insulating substrate 6. The opening 13 is provided continuously from at least one of the holes 12A. The ground terminal 8A is exposed by the communicating hole 12A and opening 13 not only toward the lower side of the insulating substrate 6 but also toward the side surface of the wiring board 2. The opening 13 will be described in detail later.

On the first surface 2a of the wiring board 2, the semiconductor chip 3 is mounted. The semiconductor chip 3 is bonded to the first surface 2a of the wiring board 2 by an adhesive layer 14. Electrode pads 15 provided on an upper surface of the semiconductor chip 3 are electrically connected to the internal connection terminals 7 of the wiring board 2 via bonding wires 16 such as Au wires. On the first surface 2a of the wiring board 2, the sealing resin layer 4 sealing the semiconductor chip 3 together with the bonding wires 16 and so on is formed. The upper surface and the side surfaces of the sealing resin layer 4 and the side surfaces of the wiring board 2 are covered by the conductive shield layer 5. The conductive shield layer 5 is electrically connected to the ground terminal 8A via a connection 17 provided in the opening 13. A structure for connecting the conductive shield layer 5 and the ground terminal 8A by using the connection 17 will be described in detail later.

The conductive shield layer 5 is preferably made of a metal material having low resistivity in view of preventing a leak to the outside of an unnecessary electromagnetic wave emitted from the semiconductor chip 3 and the wiring layers of the wiring board 2 in the sealing resin layer 4 and preventing an adverse effect to the semiconductor chip 3 of an electromagnetic wave emitted from an external device. The conductive shield layer 5 is made of at least one metal selected from copper, silver, and nickel or an alloy containing at least one of these metals, for instance. A thickness of the conductive shield layer 5 is preferably set based on its resistivity. That is, the thickness of the conductive shield layer 5 is preferably set so as to enable to obtain a low sheet resistance value which can prevent, with good reproducibility, the leakage of the unnecessary electromagnetic wave from the sealing resin layer 4 and the entrance of the electromagnetic wave emitted from the external device into the sealing resin layer 4.

The unnecessary electromagnetic wave emitted from the semiconductor chip 3 and so on and the electromagnetic wave emitted from the external device are shut off by the conductive shield layer 5 covering the sealing resin layer 4. Therefore, it is possible to prevent the leakage of the unnecessary electromagnetic wave to the outside via the sealing resin layer 4 and the entrance of the electromagnetic wave from the outside into the sealing resin layer 4. The electromagnetic waves are liable to leak or enter also from the side surfaces of the wiring board 2. Therefore, the conductive shield layer 5 preferably covers the whole side surfaces of the wiring board 2. FIG. 1B illustrates a state where the whole side surfaces of the wiring board 2 are covered by the conductive shield layer 5. Consequently, it is possible to effectively prevent the leakage and entrance of the electromagnetic waves from the side surfaces of the wiring board 2.

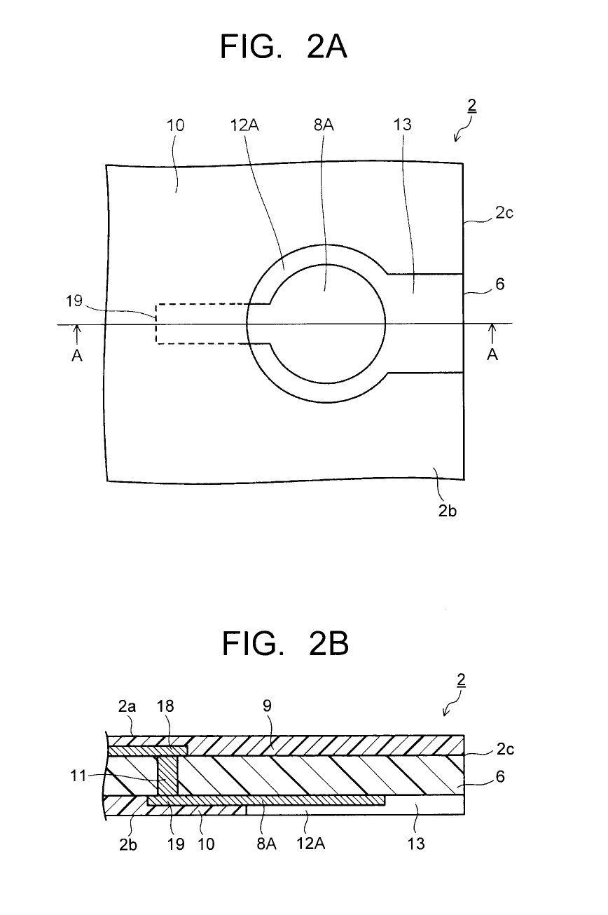

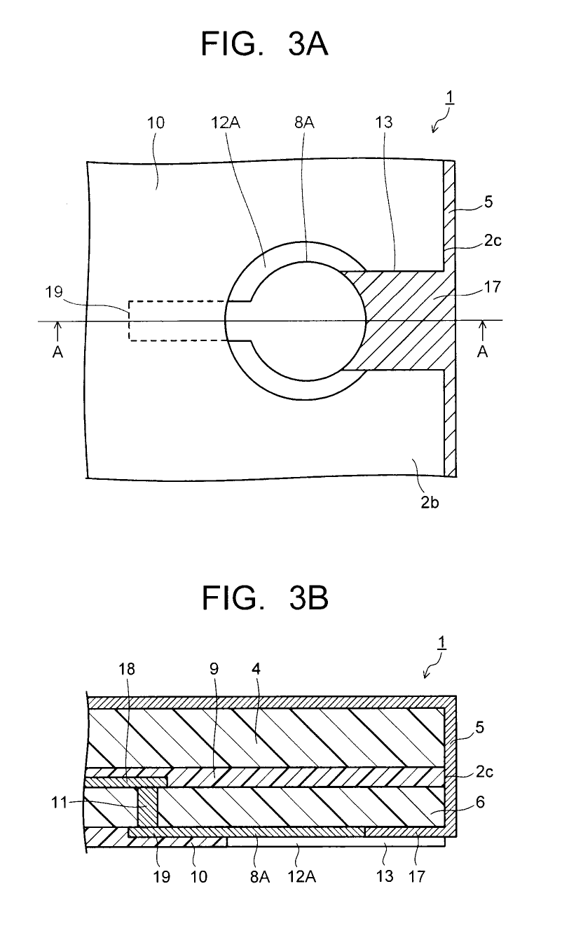

The conductive shield layer 5 is electrically connected to the ground terminal 8A through the opening 13 provided in the solder resist layer 10. The structure of the opening 13 provided in the solder resist layer 10 and the structure for electrically connecting the conductive shield layer 5 and the ground terminal 8A through the opening 13 will be described in detail with reference to FIG. 2A and FIG. 2B, and FIG. 3A and FIG. 3B. FIG. 2A is an enlarged bottom view of part of the wiring board 2 used in the semiconductor device 1. FIG. 2B is a cross-sectional view taken along A-A line in FIG. 2A. FIG. 3A is an enlarged bottom view of part of the semiconductor device 1 using the wiring board 2 illustrated in FIG. 2A and FIG. 2B. FIG. 3B is a cross-sectional view taken along A-A line in FIG. 3A.

As illustrated in FIG. 2A and FIG. 2B, the second wiring layer 19 provided on the lower surface of the insulating substrate 6 has the ground terminal 8A as part of the external connection terminals 8. The second wiring layer 19 is electrically connected to the first wiring layer 18 provided on the upper surface of the insulating substrate 6 via the vias 11. The ground terminal 8A is exposed toward the lower side of the insulating substrate 6 via the hole 12A provided in the solder resist layer 10. The ground terminal 8A is exposed toward the side surface 2c of the wiring board 2 via the opening 13 provided in the solder resist layer 10. The opening 13 is provided continuously from the hole 12A. That is, by removing a part of the solder resist layer 10 which is located between the ground terminal 8A and the side surface 2c of the wiring board 2 to be continuous from the hole 12A, the opening 13 communicating with the hole 12A is provided.

The opening 13 can be formed concurrently with the holes 12 when the holes 12 are formed in the solder resist layer 10 by exposure and development processes, for instance. That is, by exposing and developing using a mask having an open pattern corresponding to the holes 12 and the opening 13, the opening 13 communicating with the hole 12A can be formed. The opening 13 provides an area for electrically connecting the conductive shield layer 5 and the ground terminal 8A. The conductive shield layer 5 is electrically connected to the ground terminal 8A by the connection 17 provided in the opening 13.

No special wiring design is required when the conductive shield layer 5 and the ground terminal 8A are electrically connected because the opening 13 providing the electrical connection area between the conductive shield layer 5 and the ground terminal 8A is formed by removing the part of the solder resist layer 10, unlike a conventional lead-out wiring line of a ground wiring line extending to the side surface 2c of the insulating substrate 6. Since the opening 13 can be formed concurrently with the holes 12, there is no need to add any special process. Therefore, it is possible to reduce manufacturing cost of the wiring board 2 used in the semiconductor device 1 with the shieling function. Further, the opening 13 itself does not adversely affect the semiconductor device even when the conductive shield layer 5 is not formed, which makes it possible to commonly use the wiring board 2 as a wiring board used in an ordinary semiconductor device not having the shielding function. These points also contribute to cost reduction of the wiring board 2.

The semiconductor device 1 with the shielding function has the conductive shield layer 5 covering the upper surface and the side surfaces of the sealing resin layer 4 and the side surfaces of the wiring board 2 as illustrated in FIG. 3A and FIG. 3B. The conductive shield layer 5 is electrically connected to the ground terminal 8A through the opening 13. Concretely, the conductive shield layer 5 is electrically connected to the ground terminal 8A via the connection 17 provided in the opening 13. As previously described, the conductive shield layer 5 is made of the metal layer formed on the upper surface and the side surfaces of the sealing resin layer 4 and the side surfaces 2c of the wiring board 2. The connection 17 is made of a metal layer which is formed so as to be continuous from the metal layer forming the conductive shield layer 5 and to extend to the lower surface 2b of the wiring board 2.

When the conductive shield layer 5 is formed by a plating method, the connection 17 has a metal plating layer which is precipitated in the opening 13 continuously from the metal plating layer forming the conductive shield layer 5. By applying a plating condition under which the metal plating layer forming the connection 17 is connected to the ground terminal 8A, the conductive shield layer 5 and the ground terminal 8A are electrically connected via the connection 17 made of the metal plating layer. By applying such a connection 17, it is possible to electrically connect the conductive shield layer 5 and the ground terminal 8A.

The conductive shield layer 5 and the connection 17 are not limited to the metal plating layers, and each may be a metal sputtering layer, a coating layer of conductive paste, or the like. When a sputtering method or a coating method of the conductive paste is applied, by forming the metal layer (connection 17) in the opening 13 so that it continues from the metal layer (conductive shield layer 5) covering the upper surface and the side surfaces of the sealing resin layer 4 and the side surfaces of the wiring board 2 and, it is also possible to electrically connect the conductive shield layer 5 and the ground terminal 8A via the connection 17.

In electrically connecting the conductive shield layer 5 and the ground terminal 8A via the connection 17, a length of the connection 17 (distance from the side surface 2c of the wiring board 2 to the ground terminal 8A) is preferably short. When the length of the connection 17 becomes long, formability of the metal layer in the opening 13 by the plating method, the sputtering method, or the like becomes worse. The electrical connection reliability between the conductive shield layer 5 and the ground terminal 8A is decreased.

In view of these points, the conductive shield layer 5 is preferably electrically connected to the ground terminal 8A located on an outer peripheral side of the wiring board 2 (the insulating substrate 6). FIG. 2A, FIG. 2B, FIG. 3A, and FIG. 3B illustrate a state where the ground terminal 8A located on the outermost peripheral side of the wiring board 2 out of the external connection terminals 8 provided in matrix on the second (lower) surface 2b of the wiring board 2 is electrically connected to the conductive shield layer 5. This can enhance the electrical connection reliability of the conductive shield layer 5 and the ground terminal 8A via the connection 17.

The ground terminal 8A electrically connected to the conductive shield layer 5 is not limited to one. When the wiring board 2 has the plural ground terminals 8A, the plural ground terminals 8A are preferably electrically connected to the conductive shield layer 5. This can further enhance the electrical connection reliability between the ground terminals 8A and the conductive shield layer 5. In this case, the plural ground terminals 8A may be exposed toward the side surface 2c of the wiring board 2 by the openings 13 which are separately formed, or the plural ground terminals 8A may be collectively exposed toward the side surface 2c of the wiring board 2 by the single opening 13.

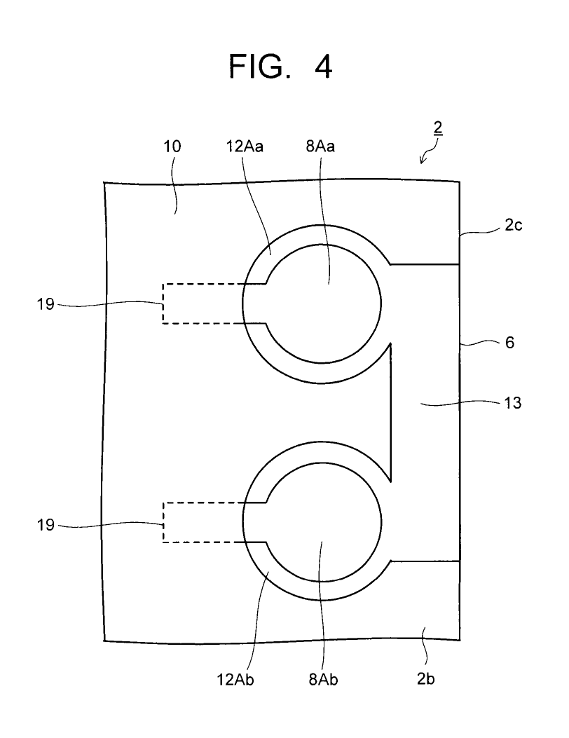

FIG. 4 illustrates the single opening 13 for exposing collectively the plural ground terminals 8A toward the side surface 2c of the wiring board 2. For a formation of the opening 13 illustrated in FIG. 4, a part (first part) of the solder resist layer 10 located between the ground terminal 8Aa and the side surface 2c of the wiring board 2 and a part (second part) of the solder resist layer 10 located between the ground terminal 8Ab adjacent to the ground terminal 8Aa and the side surface 2c of the wiring board 2 are removed continuously from an hole 12Aa and an hole 12Ab. By removing collectively a part (third part) of the solder resist layer 10 located between the first part and the second part in addition to the first and second parts of the solder resist layer 10, the opening 13 communicating with the hole 12Aa and the hole 12Ab is formed.

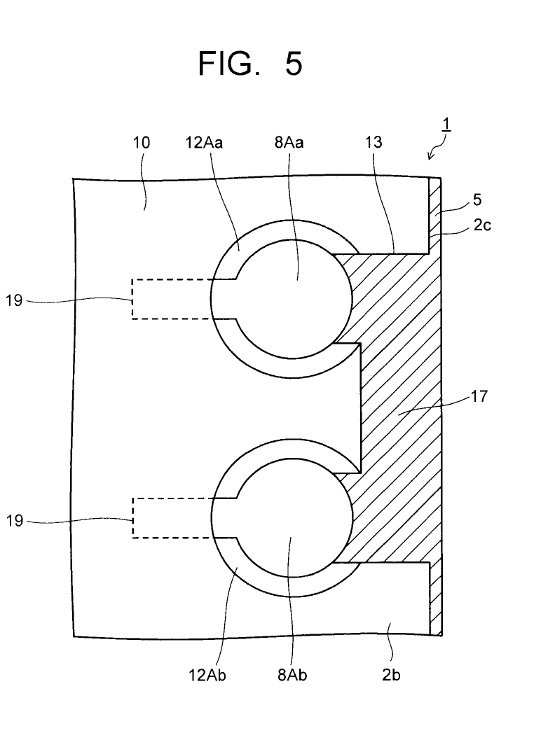

FIG. 5 illustrates a state where the conductive shield layer 5 and the ground terminals 8Aa, 8Ab are electrically connected via the connection 17 provided in the opening 13 for exposing collectively the two ground terminals 8Aa, 8Ab toward the side surface 2c of the wiring board 2. A formation area of the connection 17 includes areas for opening the hole 12Aa and the hole 12Ab outward respectively and an area between these opening areas. It is possible to set the formation area of the connection 17 wider. Therefore, the formability of the connection 17 is improved, and the electric connection reliability between the conductive shield layer 5 and the ground terminals 8Aa, 8Ab can be enhanced. In FIG. 4 and FIG. 5, the opening 13 for exposing collectively two ground terminals 8Aa, 8Ab are is illustrated, but three ground terminals 8A or more may be collectively exposed by the opening 13.

In the semiconductor device 1 of the embodiment, the connection 17 electrically connecting the conductive shield layer 5 and the ground terminal 8A is formed in the opening 13 which is provided in the solder resist layer 10 to expose one ground terminal 8A or more toward the side surface. A connection area of the conductive shield layer 5 and the ground terminal(s) 8A can be adjusted by an area of the opening 13, and thereby, it is possible to easily make the connection area larger than a conventional connection area of a ground wiring line and a shield layer. Therefore, it is possible to enhance the electrical connection reliability of the conductive shield layer 5 and the ground terminal(s) 8A. Since the connection 17 can be formed concurrently with the conductive shield layer 5 by the plating method, the sputtering method, or the like, the manufacturing cost of the semiconductor device 1 does not increase either. Further, as described above, it is also possible to reduce the manufacturing cost of the wiring board 2 itself. These make it possible to provide the semiconductor device 1 with the shielding function excellent in reliability at low price.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A wiring board, comprising:
an insulating substrate;
a first wiring layer provided on a first surface side of the insulating substrate;
a second wiring layer, provided on a second surface side of the insulating substrate, having external connection terminals including a ground terminal; and
an insulating layer, formed to cover the second wiring layer, having holes for exposing the external connection terminals respectively and an opening for exposing the ground terminal out of the external connection terminals toward a side surface of the insulating substrate, the opening being provided continuously from at least one of the holes.

2. The wiring board according to claim 1,
wherein the external connection terminals include a plurality of the ground terminals located on an outer peripheral side of the insulating substrate.

3. The wiring board according to claim 2,
wherein each of the plural ground terminals is exposed toward the side surface of the insulating substrate by the opening.

4. The wiring board according to claim 3,
wherein the opening is provided so as to collectively expose the plural ground terminals toward the side surface of the insulating substrate.

5. The wiring board according to claim 1,
wherein the opening is provided by removing a part of the insulating layer, which is located between the ground terminal and the side surface of the insulating substrate, to be continuous from at least one of the holes.

6. The wiring board according to claim 1,
wherein the insulating layer comprises a solder resist layer.

7. The wiring board according to claim 1,
wherein the insulating substrate is not provided with a wiring line extending to the side surface of the insulating substrate.

8. A semiconductor device, comprising:
the wiring board according to claim 1;
a semiconductor chip mounted on a first surface side of the wiring board having the first wiring layer, and electrically connected to the first wiring layer; and
a sealing resin layer provided on the first surface side of the wiring board to seal the semiconductor chip,
wherein a conductive shield layer is not formed on an upper surface and side surfaces of the sealing resin layer and side surfaces of the wiring board.

9. A semiconductor device, comprising:
a wiring board including first and second wiring layers respectively provided on a first surface side and a second surface side of an insulating substrate and an insulating layer covering the second wiring layer, the second wiring layer having external connection terminals including a ground terminal, and the insulating layer having holes for exposing the external connection terminals respectively and an opening for exposing the ground terminal out of the external connection terminals toward a side surface of the insulating substrate, the opening being provided continuously from at least one of the holes;
a semiconductor chip mounted on a first surface side of the wiring board having the first wiring layer, and electrically connected to the first wiring layer;
a sealing resin layer provided on the first surface side of the wiring board to seal the semiconductor chip;
a conductive shield layer provided to cover an upper surface and side surfaces of the sealing resin layer and side surfaces of the wiring board; and
a connection provided in the opening to electrically connect the ground terminal and the conductive shield layer.

10. The semiconductor device according to claim 9,
wherein the opening is provided by removing a part of the insulating layer, which is located between the ground terminal and the side surface of the wiring board, to be continuous from at least one of the holes.

11. The semiconductor device according to claim 9,
wherein the external connection terminals include a plurality of the ground terminals; and
wherein the conductive shield layer is electrically connected to the plural ground terminals.

12. The semiconductor device according to claim 9,
wherein the external connection terminals are provided in matrix on the second surface side of the insulating substrate, and the conductive shield layer is electrically connected to the plural ground terminals located on an outermost peripheral side of the wiring board out of the external connection terminals provided in matrix.

13. The semiconductor device according to claim 11,
wherein the opening is provided so as to collectively expose the plural ground terminals toward the side surfaces of the wiring board; and
wherein the conductive shield layer is electrically connected to the plural ground terminals via the connection formed in the opening.

14. The semiconductor device according to claim 13,
wherein the plural ground terminals have a first ground terminal and a second ground terminal adjacent to the first ground terminal; and
wherein the opening is provided by removing a first part of the insulating layer which is located between the first ground terminal and the side surface of the wiring board, a second part of the insulating layer which is located between the second ground terminal and the side surface of the wiring board, and a third part of the insulating layer which is located between the first part and the second part.

15. The semiconductor device according to claim 9,
wherein the conductive shield layer has a first metal layer formed on the upper surface and the side surfaces of the sealing resin layer and the side surfaces of the wiring board; and
wherein the connection has a second metal layer formed so as to be continuous from the first metal layer and to extend to a lower surface of the wiring board.

16. The semiconductor device according to claim 9,
wherein the conductive shield layer has a metal plating layer, a metal sputtering layer, or a coating layer of conductive paste.

17. The semiconductor device according to claim 16,
wherein the conductive shield layer has a first metal plating layer precipitated so as to cover the upper surface and the side surfaces of the sealing resin layer and the side surfaces of the wiring board; and
wherein the connection has a second metal plating layer precipitated in the opening so as to be continuous from the first metal plating layer.

18. The semiconductor device according to claim 9,
wherein the conductive shield layer contains at least one metal selected from the group consisting of copper, silver, and nickel.

19. The semiconductor device according to claim 9,
wherein the insulating layer comprises a solder resist layer.

20. The semiconductor device according to claim 9,
wherein a wiring line is not lead out from the side surface of the insulating substrate in the wiring board.
